(19) United States
(12) Patent Application Publication
(10) Pub. No.: US 2012/0119392 A1
(43) Pub. Date: May 17, 2012

(54) LEAD-FREE HIGH TEMPERATURE COMPOUND

(75) Inventors: Frank Breer, Mespelbrunn (DE); Wolfgang Schmitt, Rodgau (DE); Jöerg Trodler, Erlensee (DE); Karl-Heinz Schaller, Ursensollen (DE)

(73) Assignee: HERAEUS MATERIALS TECHNOLOGY GMBH & CO. KG, Hanau (DE)

(21) Appl. No.: 13/384,893

(22) PCT Filed: Jul. 21, 2010
(86) PCT No.: PCT/EP10/04447

§ 371 Date: Feb. 1, 2012

(30) Foreign Application Priority Data
Jul. 22, 2009 (DE) 10 2009 034 483.7

(51) Int. Cl. H01L 23/48; B23K 35/24; B23K 31/02

(52) U.S. Cl. 257/782; 228/180.1; 148/24; 257/E23.01

(57) ABSTRACT

A simple method is provided for firmly-bonded connection of an electronic component to a substrate, which dispenses with the use of lead-containing paste solders and leads to a contact layer featuring sufficiently high resistance to heat fatigue in an environment characterized by incessant periodical temperature variations, and featuring high thermal and electrical conductivity. The method for firmly-bonded connection of an electronic component to a substrate includes the steps of: (a) providing an electronic component having a first surface to be connected and a substrate having a second surface to be connected; (b) applying a paste solder to at least one of the surfaces to be connected; (c) arranging the electronic component and the substrate such that the first electronic component surface to be connected and the second substrate surface to be connected contact each other through the paste solder; and (d) soldering the arrangement from (c) in order to generate a firmly-bonded connection between the electronic component and the substrate, wherein the paste solder contains (i) 10-30% by weight copper particles, (ii) 60-80% by weight particles of at least one substance selected from the group consisting of tin and tin-copper alloys, and (iii) 3-30% by weight solder flux, wherein the mean particle diameter of the particles (i) and of the particles (ii) is no more than 15 μm, and wherein the thickness of the applied layer of paste solder is at least 20 μm.

### CROSS-REFERENCE TO RELATED APPLICATIONS

This application is a Section 371 of International Application No. PCT/EP2010/004447, filed Jul. 21, 2010, which was published in the German language on Jan. 27, 2011, under International Publication No. WO 2011/009597 A1 and the disclosure of which is incorporated herein by reference.

### BACKGROUND OF THE INVENTION

The present invention relates to a method for firmly-bonded connection of an electronic component to a substrate, a paste solder used in the method, and an arrangement that can be obtained in the method.

Originating from the field of microelectronics, the components are usually exposed to an environment that is characterized by incessant periodical temperature variations. This applies, in particular, to microchips that are usually connected in a firmly bonded manner to the corresponding substrates through soldering procedures which are associated with the formation of contact layers. Accordingly, it is crucial for the quality of the products used that the contact layers possess sufficient stability with respect to heat fatigue.

For this reason, it is customary to use paste solders having a high lead content of more than 85% by weight to connect chip and substrate. The lead-based paste solders impart on the connection of chip and substrate sufficient stability with respect to heat fatigue in an environment that is characterized by incessant periodical temperature variations.

According to European Union directive 2002/95/EC, it is not permissible from Jul. 1, 2006 to continue the distribution of electrical and electronic devices that contain lead or any other health-hazardous substances. As a consequence, lead-free paste solders were developed for various electrical and electronic applications. However, solders for use in high temperature applications are one exception from the rule of the directive. Considering the lack of alternatives, the use of lead is still permissible in this area, at least until equivalent lead-free alternatives are available. Accordingly, the aim is to develop arrangements made up of chips and substrates that comprise no lead-containing contact layers.

The lead-free paste solders, which have been used as an alternative for firmly-bonded connection of chips and substrates thus far, are fusible paste solders that usually contain, aside from a soldering flux, powder having particles made of a metal alloy that mainly consists of tin, silver and/or copper, whereby the mean particle diameter of the particles is 25-45 μm or more.

Studies have shown that the contact layers generated through the use of the paste solders consist not only of solder microstructure, but also contain highly temperature-resistant metallic compounds, so-called inter-metallic phases. Here, the inter-metallic phases and the eutectic phase of the solder microstructure extend essentially parallel to each other and to the surfaces of chip and substrate to be connected and thus form a sandwich structure. Since the different phases of the sandwich structure differ in their thermal expansion coefficients, the contact sites show only limited thermal and mechanical resistance.

Moreover, attempts have been made to generate firmly-bonded connections of chip and substrate through diffusion soldering. In this context, a solder material that melts at low temperature and metals melting at high temperature form a highly temperature-resistant and mechanically stable inter-metallic phase. The solder material is converted completely to the inter-metallic phase in this process.

German published patent application DE 10 2007 010 242 A1, for example, discloses a method for attaching chips on substrates through diffusion soldering. For this purpose, according to DE 10 2007 010 242 A1, solid solder layers a few micrometers in thickness are applied initially onto the metal surfaces to be connected through sputtering and electroplating, which necessitates two thermal steps for application of the solid solder reservoir. Subsequent diffusion soldering then generates a contact layer between the chip and the substrate that contains inter-metallic phases only. This imparts more strength to the contact thus generated as compared to a contact site of the same thickness made through fusion soldering. On the other hand, it would be desirable, though, to increase the thickness of the contact layer in order to attain even higher strength by this means.

### BRIEF SUMMARY OF THE INVENTION

For this reason, it is the object of the invention to provide a simple method for firmly-bonded connection of an electronic component to a substrate that dispenses with the use of lead-containing paste solders and leads to a contact layer that features sufficiently high resistance to heat fatigue in an environment that is characterized by incessant periodical temperature variations, and that features high thermal and electrical conductivity.

The object is met by a method for firmly-bonded connection of an electronic component to a substrate, comprising:

a) providing an electronic component having a first surface to be connected and a substrate having a second surface to be connected;

b) applying a paste solder to at least one of the surfaces to be connected;

c) arranging the electronic component and the substrate such that the first electronic component surface to be connected and the second substrate surface to be connected contact each other by means of the paste solder; and

d) soldering the arrangement from c) in order to generate a firmly-bonded connection between the electronic component and the substrate, wherein the paste solder contains (i) 10-30% by weight copper particles, (ii) 60-80% by weight particles of at least one substance selected from the group consisting of tin and tin-copper alloys, and (iii) 3-30% by weight solder flux, wherein the mean particle diameter of the copper particles and of the particles made of a substance selected from the group consisting of tin and tin-copper alloys is no more than 15 μm, and wherein the thickness of the applied layer of paste solder is at least 20 μm.

Accordingly, this method involves the use of a paste solder that contains:

(i) 10-30% by weight copper particles;

(ii) 60-80% by weight particles of at least one substance selected from the group consisting of tin and tin-copper alloys; and

(iii) 3-30% by weight solder flux,

wherein the mean particle diameter of the copper particles and of the particles made of at least one substance selected from the group consisting of tin and tin-copper alloys is no more than 15 μm.

Accordingly, the scope of the invention entails providing an arrangement comprising an electronic component, a substrate and an intervening contact layer connecting the electronic component and the substrate in a firmly bonded manner, wherein the contact layer comprises a eutectic phase fraction and an inter-metallic phase fraction, and wherein the eutectic phase fraction is in the range of 5-50% by weight based on the total weight of eutectic phase and inter-metallic phase.

The method according to the invention is based on the surprising finding that, in the course of soldering the arrangement made up by substrate, electronic component and intervening paste solder according to the invention, the soldering material initially solidifies thermally which leads to attachment of substrate and electronic component through an intermediate contact layer that is formed and initially consists of eutectic phase only. Right thereafter, the intermediate contact layer formed undergoes isothermal solidification which is associated with the formation of inter-metallic phases. In the process, the eutectic phase becomes interspersed with inter-metallic phase, whereby the phase boundaries formed between inter-metallic phase and the remaining contact layer do not extend parallel to each other and to the surfaces of electronic component and substrate, but form a contact layer having a eutectic phase fraction and an inter-metallic phase fraction, wherein the eutectic phase fraction is in the range of 5-50% by weight based on the total weight of eutectic phase and inter-metallic phase.

The formation of the contact layers leads to a substantial increase in strength as compared to both a thin contact layer (just a few millimeters thick) generated through diffusion soldering, which contains just inter-metallic phase, and a contact layer generated through fusion soldering, which comprises both eutectic and inter-metallic phases extending essentially parallel to the surfaces to be connected, and contains mainly eutectic phase. Accordingly, problems associated with the surface roughness of the objects to be connected, the limited application of solder in diffusion soldering and the warpage (warping of the surface during the soldering process) can be resolved, which leads to a more stable connection of substrate and electronic component.

Accordingly, contact layers can be generated according to the invention that feature the typical high temperature resistance of contact layers formed through diffusion soldering without the thermal and electrical conductivity being reduced.

It has been found that it is essential for the formation of the stable contact layers to select a sufficiently thickness of the applied layer of the paste solder. If the thickness of the applied layer is just few micrometers, soldering leads to the formation of inter-metallic phases right away, whereby later interspersing by eutectic phase is excluded. This does not allow the increase of strength, as is to be provided according to the invention, to be attained.

Moreover, it has been evident that the desired increase in strength is attained only if a certain quantity of copper particles of a certain size is added. Without wishing to be limited by one particular theory, copper originating from the copper particles appears to diffuse into an intermediary eutectic phase formed during the cooling to below the liquidus temperature of the solder which is associated with the formation of an inter-metallic phase that is interspersed with eutectic phase.

### DETAILED DESCRIPTION OF THE INVENTION

In the scope of the invention, the term “electronic component” shall be understood to mean a component of an electrical circuit. The electrical component can, for example, be a chip, preferably a bare chip (semi-conductor chip without housing), a semi-conductor diode, a transistor, a resistor or a capacitor.

In the scope of the invention, the term “substrate” shall be understood to mean a body to which the electronic component is connected. The substrate can, for example, be a printed circuit board, direct-bonded copper (DBC or DCB) or a lead frame.

The term “printed circuit board” is used herein as a synonym of printed circuit card, board or printed circuit and describes a carrier for electronic components. Printed circuit boards consist of electrically insulating material to which conductive connections adhere (printed conductors). Fiber-reinforced plastic material, for example, can be used as electrically insulating material.

“Direct-bonded copper” is a term used to refer to a ceramic plate (for example made of alumina, aluminum nitride or beryllium oxide), wherein one surface or the two surfaces with the largest area that are parallel to each other are bonded with copper through an oxidation process at high temperatures. At the selected conditions, a eutectic mixture of copper and oxygen is formed that becomes connected to both the copper and the substrate oxide.

A lead frame shall be understood to be an IC (integrated circuit, microchip) housing that essentially consists of a chip carrier and connecting leads only. The term “lead frame” is used herein as a synonym of the terms “connecting frame” and “chip carrier.” The chip carrier comprises a substrate that constitutes its base frame and is fabricated from metal, e.g. copper, copper alloys, a combination of copper and a finisher (e.g. nickel, silver or gold), iron-nickel alloys or other invar alloys.

The electronic component comprises at least one first surface, that is intended to be used for connecting the electronic component to a surface of the substrate by means of the contact layer generated by the paste solder. The surface can just as well be part of a larger surface.

The substrate comprises at least a second surface that is intended to be used for connecting the substrate to the surface of the electronic component described above by means of the contact layer generated by the paste solder. The surface also can just as well be part of a larger surface.

According to the invention, the surface of the electronic component that is connected to the substrate by means of the contact layer generated by the paste solder is called “first surface to be connected,” and the surface of the substrate that is connected to the electronic component by means of the contact layer generated by the paste solder is called “second surface to be connected.”

Customarily, a metallization layer has been applied at least to the first electronic component surface to be connected. It is also customary for a metallization layer to have been applied at least to the second substrate surface to be connected. Customarily, both electronic component and substrate contain a metallization layer at least on the surfaces to be connected. It is therefore customary that the electronic component comprises a metallization layer on a surface that is situated opposite from a metallization layer on the surface of the substrate and that the metallization layers are connected to each other through the contact layer. In the scope of the invention, the metallization layers that may be contained in the electronic component are part of the electronic component and the metallization layers that may be contained in the substrate are part of the substrate.

If present, the metallization layer preferably accounts for an area of at least 50%, more preferably at least 70%, even more preferably at least 90%, and particularly preferably at least 95%, such as, for example, 100%, of at least one of the surfaces of the electronic component. On the substrate, the metallization layer preferably accounts for an area of at least 50%, more preferably at least 70%, even more preferably at least 90%, and particularly preferably at least 95%, such as, for example, 100%, of the surface that is connected to the electronic component through the contact layer.

The metallization layer preferably is a layer that contains connections that can be soldered. The metallization layer preferably contains an element selected from the group consisting of copper, silver, gold, tin, and palladium. The metallization layer can just as well consist entirely of the elements, solderable compounds of the elements or mixtures or alloys of the elements.

According to the invention, a paste solder is applied to at least one of the electronic component surfaces or substrate surfaces to be connected.

The paste solder contains (i) 10-30% by weight copper particles, (ii) 60-80% by weight particles of at least one substance selected from the group consisting of tin and a tin-copper alloy, and (iii) 3-30% by weight solder flux.

The purity of the copper of the copper particles contained in the paste solder preferably is at least 99.9% (3 N) and more preferably at least 99.99% (4 N).

The copper particle fraction of the paste solder is 10-30% by weight, preferably 12-28% by weight, and more preferably 15-25% by weight based on the weight of the paste solder.

The fraction of particles of at least one substance selected from the group consisting of tin and a tin-copper alloy is 60-80% by weight, preferably 62-78% by weight, and more preferably 65-75% by weight based on the weight of the paste solder.

If the paste solder contains particles of a tin-copper alloy, the tin fraction is preferably in the range from 97-99.5% by weight and more preferably in the range from 98-99.5% by weight, and the copper fraction is preferably in the range from 0.5-3% by weight and more preferably in the range from 0.5-2% by weight. According to a particularly preferred embodiment, the tin-copper alloy is an alloy that comprises 99.3% by weight tin and 0.7% by weight copper.

According to the invention, it is essential that the particles contained in the paste solder have a small average particle diameter. Only paste solders comprising particles with sufficiently small average particle diameters are well-suited to initially form a eutectic phase during the soldering for attachment of electronic component and substrate and then enable the interspersing of the eutectic phase by inter-metallic phase.

The mean particle diameter of the copper particles and the mean particle diameter of the particles of at least one substance selected from the group consisting of tin or a tin-copper alloy, are independent of each other and are no more than 15 μm, preferably no more than 13 μm, more preferably no more than 11 μm, and yet more preferably no more than 8 μm. Preferably, the mean particle diameter is in the range from 2-15 μm, more preferably in the range from 2-13 μm, even more preferably in the range from 2-11 μm, and yet even more preferably in the range from 2-8 μm.

In the scope of the invention, “mean particle diameter” shall be understood to mean that at least 90 per cent of the particles have a particle diameter in the specified range. For example, a mean particle diameter being no more than 15 μm means that at least 90 per cent of the particles have a particle diameter of no more than 15 μm and less than 10 per cent of the particles have a particle diameter of more than 15 μm. A mean particle diameter being in the range from 2-15 μm means that at least 90 per cent of the particles have a particle diameter in the range from 2-15 μm and less than 10 per cent of the particles have a particle diameter of less than 2 μm or more than 15 μm.

It can be preferred according to the invention that less than 1 per cent of the particles exceed a certain particle diameter. The particle diameter that may be exceeded by less than 1 per cent of the particles, preferably is 15 μm, more preferably 11 μm, and even more preferably 8 μm.

Moreover, it can also be preferred according to the invention that the paste solder contains no particles having a particle diameter of more than 20 μm, of more than 18 μm, of more than 15 μm, or of more than 11 μm.

The geometries of the copper particles and of the particles of at least one substance selected from the group consisting of tin and a tin-copper alloy, can be different. However, the particles preferably are spherical in shape. However, it is obvious to the person skilled in the art that a minor fraction of the particles employed can be non-spherical in shape for production reasons. However, preferably at least 90% by weight, more preferably at least 95% by weight, even more preferably at least 99% by weight or 100% by weight, of the particles that are present are spherical in shape. It is also preferred that the paste solder contains less than 5% by weight, more preferably less than 1% by weight, even more preferably less than 0.1% by weight, for example 0% by weight, particles in the shape of flakes.

According to the invention, the paste solder contains 3-30% by weight, preferably 5-20% by weight, and more preferably 6-15% by weight solder flux. The solder flux should be capable of reducing the surface during the soldering (i.e., to de-oxidize), prevent renewed oxide formation before and after the soldering process and reduce the inclusion of foreign substances. Moreover, addition of the solder flux should reduce the surface tension of the liquid solder. Solder flux that can be used includes colophony, colophony-based resin systems, water-based resin systems or systems based on carbonic acids (e.g., carbonic acids having 2-50 C atoms and up to two aromatic rings, such as citric acid, adipic acid, cinnamic acid and benzoic acid), amines (e.g., amines having 6-100 C atoms, with the amines preferably being tertiary), and solvents (e.g., polar solvents including water and a polyol, such as glycol or glycerol).

Moreover, the paste solder according to the invention can contain further ingredients such as, for example, alcohols, fatty acids (e.g., saturated fatty acids, such as oleic acid, myristic acid, palmitic acid, margaric acid, stearic acid or eicosanoic acid), polysiloxane compounds or phosphide compounds.

The paste solder employed according to the invention contains no lead and is thus lead-free. In the scope of the invention, being lead-free shall be understood to mean that the paste solder contains no lead except for contaminating lead that may possibly be present for technical reasons. Accordingly, “lead-free” shall be understood to mean a lead content of less than 1, preferably of less than 0.5, more preferably of less than 0.1, even more preferably of less than 0.01% by weight and in particular of 0% by weight, based on the weight of the paste solder.

According to the invention, electronic component and substrate are connected to each other in a firmly-bonded manner through soldering. Accordingly, firmly-bonded connections are connections in which the connected partners are kept together through atomic or molecular forces. They preferably are non-separable connections that can be separated only by destroying the connecting means.

According to the invention, an arrangement is formed first that consists of the substrate, the electronic component, and a paste solder layer situated between substrate and electronic component. Accordingly, substrate and electronic component are arranged such that the first substrate surface to be connected and the second electronic component surface to be connected contact each other through the paste solder. Usually, the paste solder preferably contacts the metallization layer of the substrate, if present, and the metallization layer of the electronic component, if present.

Preferably, for this purpose, a layer of paste solder is first applied to the substrate surface to be connected, preferably to the substrate surface containing a metallization layer. The application can be effected through any of the methods known according to the prior art, for example screen printing methods, stencil printing method or dispensing technique. There is no need for the paste solder to cover the entire surface of the substrate. Rather, the paste solder can just as well be applied to parts of the surface of the substrate and/or selected soldering surfaces only. Subsequently, a surface of the electronic component, preferably the surface containing the metallization layer, is placed onto the paste solder thus applied.

According to the invention, the thickness of the applied layer of paste solder is at least 20 μm, more preferably at least 25 μm, and even more preferably at least 50 μm. According to a preferred embodiment, the thickness of the applied layer is in the range from 20-150 μm, more preferably in the range from 30-120 μm, and particularly preferably in the range from 50-100 μm. In the scope of the invention, the term “thickness of the applied layer” shall be understood to mean the distance between the surfaces of substrate and electronic component to be connected, preferably between the metallization layers of the surfaces of substrate and electronic component to be connected, right before soldering. Accordingly, the thickness of the applied layer is determined essentially by the quantity of paste solder employed. During the subsequent solder process, the distance between electronic component and substrate is reduced significantly, possibly by approximately 50 per cent, depending on the exact composition of the paste solder. This is due to evaporation of the solder flux during the soldering process, amongst other factors.

The arrangement made up by electronic component, substrate and intervening paste solder is finally soldered which is associated with the formation of an arrangement made up by electronic component, substrate, and intervening contact layer. According to general definition, “soldering” shall be understood to mean a thermal method for firmly-bonded joining and coating of materials without reaching the solidus temperature of the materials.

For soldering, the arrangement described above is heated, preferably evenly until the actual soldering temperature is reached. According to a preferred embodiment, the heating proceeds at a rate of no more than 3° C. per second.

Preferably, the soldering temperature is approx. 10-30° C., more preferably approx. 15-25° C., and even more preferably 18-22° C., for example approx. 20° C., above the melting temperature of the solder employed. According to another preferred embodiment, the soldering temperature is below 260° C., for example in the range from 240-250° C.

For soldering, the temperature is kept above the liquidus temperature of the solder contained in the paste solder for a period of at least 15 seconds, preferably of at least 20 seconds, and even more preferably of at least 30 seconds.

According to the invention, cooling the soldered arrangement to below the liquidus temperature of the solder contained in the paste solder is associated with diffusion of the copper originating from the copper particles into the eutectic tin-copper phase that has been generated during the soldering process. The diffusion process ultimately leads to inter-metallic phase interspersing the eutectic phase and consequently to an increase of the strength of the contact generated before.

In order to enhance this effect, it may be advantageous to subject the arrangement made up by electronic component, substrate and intervening contact layer that is obtained during the soldering process to a heat treatment following the soldering process. Heat treatment shall be understood to mean treating the arrangement with heat below the liquidus temperature of the solder.

The heat treatment preferably proceeds at a temperature above 40° C., for example in the range from 40-217° C., more preferably in the range from 100-210° C., and even more preferably in the range from 150-205° C. The heat treatment preferably proceeds for a duration of 1 minute to 24 hours, more preferably for 10 minutes to 10 hours, and even more preferably for 20 minutes to 1 hour. The duration of heat treatment is usually correlated with the temperature and is the longer, the lower the temperature used for heat treatment.

It is particularly advantageous for the method according to the invention to require no expensive modifications be made to the customary methods for the production of arrangements made up by electronic component, substrate, and intervening contact layer. In particular, the method according to the invention is not associated with particular requirements regarding the machinery used for conventional soldering processes. The method according to the invention can therefore be carried out, for example, at conventional conditions and using existing machinery, if any.

According to a preferred embodiment, the arrangement according to the invention can be or is produced by means of the method described above.

Surprisingly, the method described above has been found to impart superior properties to the arrangement made up by electronic component, substrate, and intervening contact layer produced according to the invention. Accordingly, providing the lead-free contact layer, which connects electronic component and substrate to each other, is associated with increased reliability as compared to arrangements having contact layers that are produced according to conventional methods.

Surprisingly, this is based on the contact layer produced according to the invention being a eutectic phase that is interspersed with inter-metallic phase.

Owing to the eutectic phase being interspersed with inter-metallic phases, the formation of long boundary regions between eutectic and inter-metallic phases that extend parallel to the surfaces of substrate and electronic component is prevented. Accordingly, the contact layers comprise no extensive boundary regions of phases with different thermal expansion coefficients, which allows increased strength to be attained.

Therefore, the arrangement according to the invention made up by substrate, electronic component, and intervening contact layer is capable of withstanding the strong periodical temperature variations that occur, in particular, during the operation of high performance semiconductors.

Accordingly, the arrangement comprises an electronic component, a substrate and a contact layer disposed in between the electronic component and the substrate, wherein the contact layer comprises a eutectic phase fraction and an inter-metallic phase fraction, and wherein the eutectic phase fraction is in the range of 5-50% by weight based on the total weight of eutectic phase and inter-metallic phase.

The high fraction of inter-metallic phase at the contact layer, with the remainder being eutectic phase, is attained in that the inter-metallic phases are not arranged so to be parallel to the surfaces of electronic component and substrate to be connected and to the eutectic phase, but rather in that they are mingled with the latter.

The fraction of inter-metallic phase and eutectic phase can be determined, for example, through an etching and gravimetric method. For this purpose, the contact layer to be tested is separated from the arrangement, ground and weighed in order to determine the total weight of the contact layer consisting of eutectic phase and inter-metallic phase. Subsequently, 2-nitrophenol is added to the ground contact layer and the sample is kept at 50° C. for one hour. During this deep etching, the eutectic phase is dissolved from the ground contact layer, whereas inter-metallic phases stay behind as insoluble ingredients. The fraction of eutectic phase is then determined as the weight difference of the weight of the ground contact layer before etching and the weight of the inter-metallic phase.

The contact layer contained in the arrangement according to the invention has the eutectic phase and the inter-metallic phase not arranged to be essentially parallel to each other and to the surfaces of electronic component and substrate to be connected. Rather, the contact layer preferably contains eutectic phases that are surrounded by inter-metallic phases. According to a preferred embodiment, the contact layer contains bodies of eutectic phase having a volume of at least 1,000 μm³ that are fully surrounded by inter-metallic phase. Preferably, the fraction of the bodies in the contact layer is at least 1% by volume, more preferably at least 3% by volume, and even more preferably at least 5% by volume. The fraction of the bodies in the contact layer can be determined easily through analysis of microsections.

In the arrangement according to the invention, the distance between electronic component and substrate preferably is 8-50 μm, more preferably 10-30 μm, and even more preferably 12-28 μm. The distance shall be understood to mean the distance between the surfaces of electronic component and substrate to be connected, wherein the metallization layers, which may be present, are part of the electronic component or substrate. The specified distance thus corresponds to the thickness of the contact layer between electronic component and substrate after soldering.

According to the invention, the soldering conditions, in particular the thickness of the applied layer of paste solder, temperature and time, and, if applicable, the heat treatment conditions, in particular temperature and time, can be adjusted in the soldering process described above such that the contact layer described above is attained. The formation of the contact layer having the desired properties can be traced easily through analysis of corresponding microsections.

The invention is further illustrated below through the following examples, though these may not be construed such as to limit the invention in any way or form.

### EXAMPLES

### Example 1

A paste solder containing 74% by weight particles of a tin-copper alloy (SnCu0.7) having an average particle diameter in the range from 5-15 μm, 15% by weight copper particles having an average particle diameter of up to 5 μm, and 11% by weight of a solder flux system based on colophony was prepared.

The paste solder was applied through a metal template onto a DCB substrate provided with a metallization layer made of copper. The thickness of the applied layer of paste solder was 20 μm.

Subsequently, the surface of the DCB substrate provided with paste solder was provided with a bare chip having a surface area of approx. 400 mm² and a metallization layer made of copper using a dedicated machine for this purpose. For this purpose, the bare chip was placed on the paste solder in such a manner that the metallization layer of the bare chip contacted the metallization layer of the DCB substrate via the paste solder.

The arrangement made up by DCB substrate, bare chip, and intervening paste solder was then placed in a soldering furnace, heated at a rate of 2.5 Kelvin per second to a temperature of 245° C., and the temperature was maintained for 30 seconds for soldering.

### Reference Example 1

A paste solder containing 87% by weight particles of a tin-copper alloy (SnCu0.7) having an average particle diameter in the range from 5-15 μm, and 13% by weight of a solder flux system based on colophony was prepared.

The paste solder was applied through a metal template onto a DCB substrate provided with a metallization layer made of copper. The thickness of the applied layer of paste solder was 20 μm.

Subsequently, the surface of the DCB substrate provided with paste solder was provided with a bare chip having a surface area of approx. 400 mm² and a metallization layer made of copper using a dedicated machine for this purpose. For this purpose, the bare chip was placed on the paste solder in such a manner that the metallization layer of the bare chip contacted the metallization layer of the DCB substrate via the paste solder.

The arrangement made up by DCB substrate, bare chip, and intervening paste solder was then placed in a soldering furnace, heated at a rate of 2.5° C. per second to a temperature of 245° C., and the temperature was maintained for 30 seconds for soldering.

In various experiments investigating the stability of the arrangements prepared according to the Example and Reference Example, it was found that the arrangement prepared according to the invention proved to be more heat resistant as compared to the arrangement prepared according to the Reference Example.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-7. (canceled)

8. A method for producing a firmly-bonded connection of an electronic component to a substrate, comprising steps of:
(a) providing an electronic component having a first surface to be connected and a substrate having a second surface to be connected;
(b) applying a paste solder to at least one of the first and second surfaces to be connected;
(c) placing the electronic component and the substrate in an arrangement such that the first surface to be connected and the second surface to be connected contact each other through the paste solder; and
(d) soldering the arrangement from step (c) to generate the firmly-bonded connection between the electronic component and the substrate;
wherein the paste solder contains (i) 10-30% by weight copper particles, (ii) 60-80% by weight particles of at least one substance selected from the group consisting of tin and tin-copper alloys, and (iii) 3-30% by weight solder flux, wherein a mean particle diameter of the copper particles and of the particles made of at least one substance selected from the group consisting of tin and tin-copper alloys is no more than 15 μm, and wherein the thickness of the applied layer of paste solder is at least 20 μm.

9. The method according to claim 8, further comprising a step of:
(e) subjecting the arrangement of step (d) to a heat treatment at a temperature of at least 40-217° C. for a period of time in a range of 1 minute to 24 hours.

10. The method according to claim 8, wherein the substrate is selected from the group consisting of a printed circuit board, a lead frame, and a direct-bonded copper substrate.

11. The method according to claim 8, wherein the paste solder contains particles of a tin-copper alloy having a copper fraction in a range of 0.3-5% by weight.

12. A paste solder comprising (i) 10-30% by weight copper particles, (ii) 60-80% by weight particles of at least one substance selected from the group consisting of tin and tin-copper alloys, and (iii) 3-30% by weight solder flux, wherein a mean particle diameter of the copper particles and of the particles made of at least one substance selected from the group consisting of tin and tin-copper alloys is no more than 15 μm.

13. The paste solder according to claim 12, wherein the paste solder contains particles of a tin-copper alloy having a copper fraction in a range from 0.3-5% by weight.

14. An arrangement comprising an electronic component, a substrate and an intervening contact layer connecting the electronic component and the substrate in a firmly-bonded manner, wherein the contact layer comprises a eutectic phase fraction and an inter-metallic phase fraction, and wherein the eutectic phase fraction is in a range of 5-50% by weight based on a total weight of the eutectic phase and inter-metallic phase fractions.
